(19) United States
(12) Patent Application Publication
(10) Pub. No.: US 2025/0292842 A1
(43) Pub. Date: Sep. 18, 2025

(54) STORAGE DEVICE

(71) Applicant: Kioxia Corporation, Tokyo (JP)

(72) Inventor: Yoshikazu HARADA, Kawasaki Kanagawa (JP)

(21) Appl. No.: 18/883,321

(22) Filed: Sep. 12, 2024

(30) Foreign Application Priority Data
Mar. 18, 2024 (JP) 2024-042696

(51) Int. Cl. G11C 16/26; G11C 16/04; G11C 16/08; G11C 16/10; G11C 16/34

(52) U.S. Cl. CPC G11C 16/26; G11C 16/0483; G11C 16/08; G11C 16/10; G11C 16/3459

(57) ABSTRACT

A semiconductor storage device that stores data with high accuracy is provided. The semiconductor storage device includes a memory cell transistor, a bit line connected to the memory cell transistor, a word line connected to the memory cell transistor, a sense amplifier connected to the memory cell transistor, and a control circuit configured to execute a first operation. The first operation includes acquiring first data using the sense amplifier based on a first current flowing to the bit line while a first voltage is applied to the word line, and then acquiring second data using the sense amplifier based on a second current flowing to the bit line while the word line is placed in an electrically floating state.

### CROSS-REFERENCE TO RELATED APPLICATION(S)

This application is based upon and claims the benefit of priority from Japanese Patent Application No. 2024-042696, filed Mar. 18, 2024, the entire contents of which are incorporated herein by reference.

### FIELD

Embodiments described herein relate generally to a storage device.

### BACKGROUND

There exist requirements for a storage device to accurately store data and to accurately output data. Accurate data storage and output may not be possible because of defective components in the storage device.

### DESCRIPTION OF THE DRAWINGS

FIG. 1 illustrates an example of components of a storage device of a first embodiment.

FIG. 2 is a circuit diagram of components in one block of the storage device of the first embodiment.

FIG. 3 is a schematic cross-sectional view of a part of a memory cell array in the storage device of the first embodiment.

FIG. 4 illustrates an example of a distribution of threshold voltages of cell transistors storing 3-bit data in the storage device of the first embodiment.

FIG. 5 illustrates components of a driver and a row decoder in the storage device of the first embodiment.

FIG. 6 illustrates elements and connections of a sense amplifier in the storage device of the first embodiment.

FIG. 7 is a circuit diagram of the sense amplifier circuit in the storage device of the first embodiment.

FIG. 8 is a timing diagram illustrating a write operation in the storage device of the first embodiment.

FIG. 9 illustrates an example of verification targets of each program loop of the write operation carried out in the storage device of the first embodiment.

FIG. 10 is a timing diagram illustrating voltage changes in various wires and signals during a write verification process carried out in the storage device of the first embodiment.

FIG. 11 is a timing diagram illustrating voltage changes in a selected word line during the write verification process carried out in the storage device of the first embodiment.

FIGS. 12-14 each illustrate an example of a state and acquired data during the write verification process carried out in the storage device of the first embodiment.

FIG. 15 illustrates an example of input/output signals transmitted and received by the storage device during the write operation carried out in the storage device of the first embodiment.

FIGS. 16-19 each illustrate a different example of when a floating verify operation is performed in the storage device of the first embodiment.

FIG. 20 illustrates another example of input/output signals transmitted and received by the storage device during the write operation carried out in the storage device of the first embodiment.

### DETAILED DESCRIPTION

Embodiments provide a semiconductor storage device that stores data with high accuracy.

In general, according to one embodiment, a semiconductor storage device includes a memory cell transistor, a bit line connected to the memory cell transistor, a word line connected to the memory cell transistor, a sense amplifier connected to the memory cell transistor, and a control circuit configured to execute a first operation. The first operation includes acquiring first data using the sense amplifier based on a first current flowing to the bit line while a first voltage is applied to the word line, and then acquiring second data using the sense amplifier based on a second current flowing to the bit line while the word line is placed in an electrically floating state.

Hereinafter, the embodiment will be described with reference to the drawings. A plurality of components having substantially same function and configuration in one embodiment or different embodiments may have additional numbers or letters added to an end of reference signs to distinguish them from each other. All descriptions of one embodiment also apply as descriptions of other embodiments, unless explicitly or obviously excluded.

In the present specification and claims, a certain first element being “connected” to another second element includes the first element being connected to the second element directly or via an element which is normally or selectively conductive.

Hereinafter, the embodiment is described using a three-dimensional Cartesian coordinate system. A direction of the x-axis is referred to as an X-direction. A direction opposite to the X-direction is referred to as a-X-direction. A direction of the y-axis is referred to as a Y-direction. A direction opposite to the Y-direction is referred to as a-Y-direction. A direction of the z-axis is referred to as a Z-direction, and an upward direction is the Z-direction. A direction opposite to the Z-direction is referred to as a-Z-direction, and a downward direction is the-Z-direction.

### 1. First Embodiment

### 1.1. Configuration (Structure)

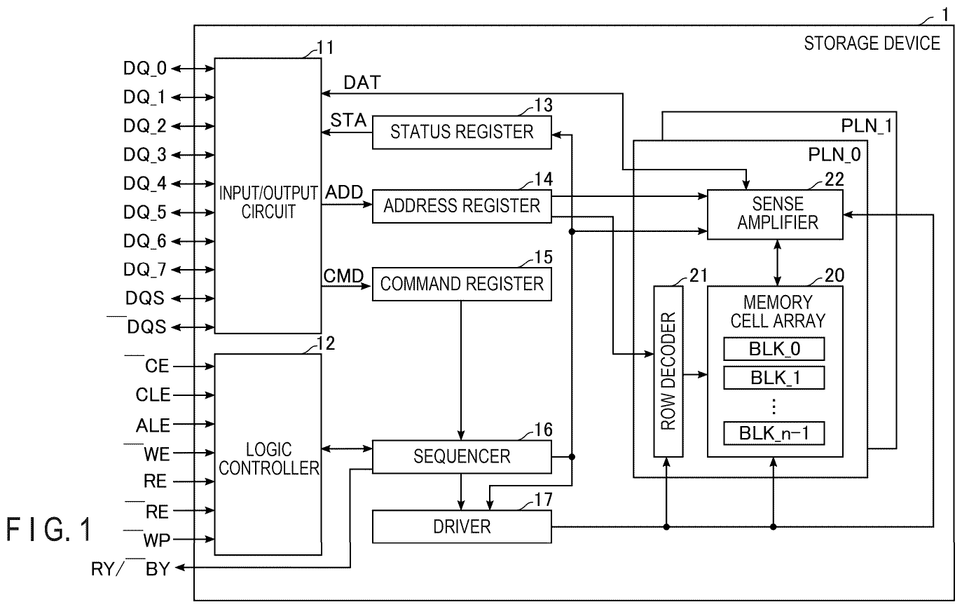

FIG. 1 illustrates an example of components of a storage device of the first embodiment and connections of the components. A storage device 1 stores data using a memory cell. The storage device 1 stores written data, and outputs the data stored in the storage device 1. In one example, the storage device 1 is implemented as one chip.

The storage device 1 includes the components such as a plurality of, two for example, planes PLN_0 and PLN_1, an input/output circuit 11, a logic controller 12, a status register 13, an address register 14, a command register 15, a sequencer 16, and a driver 17.

Each plane is a set of a plurality of components. The plane PLN is a target (or, a memory region) for data write and data read. The planes PLN can be operated independently of each other and can also be operated in parallel. In other words, the storage device 1 includes the plurality of memory regions that can be controlled independently of each other. Each plane PLN includes the same component set, and includes components such as a memory cell array 20, a row decoder 21, and a sense amplifier 22.

The memory cell array 20 is a set of arrayed memory cells. The memory cell array 20 includes a plurality of memory blocks (or, blocks) BLK. Each block BLK includes a plurality of cell transistors MT (not illustrated). In a region where the memory cell array 20 is provided, wires such as a word line WL (not illustrated) and a bit line BL (not illustrated) are also arranged.

The input/output circuit 11 transmits and receives various signals to/from outside the storage device 1, a memory controller for example. The input/output circuit 11 transmits and receives input/output signals DQ (DQ_0, DQ_1, DQ_2, DQ_3, DQ_4, DQ_5, DQ_6, and DQ_7), and signals DQS and ⁻DQS. A sign “⁻” indicates inverted logic of a signal having a name following the sign “⁻”, and also indicates that the signal is asserted when it is at a low (“L”) level. A set of the input/output signals DQ_0 to DQ_7 functions as signals containing a command (CMD), write data or read data (DAT), address information (ADD), and a status (STA) or the like. The signals DQS and ⁻DQS indicate a timing of fetching the input/output signals DQ_0 to DQ_7.

The logic controller 12 transmits and receives signals to/from outside the storage device 1, the memory controller for example. The logic controller 12 receives signals ⁻CE, CLE, ALE, ⁻WE, RE, ⁻RE, and ⁻WP. The signal ⁻CE indicates that the storage device 1 should be enabled. The signal CLE indicates transmission of the command through the input/output signals DQ. The signal ALE indicates transmission of the address information ADD through the input/output signals DQ. The signal WE indicates that the input/output signals DQ should be fetched. The signals RE and ⁻RE indicate the timing of outputting the input/output signals DQ.

The status register 13 temporarily stores status information STA. The status information STA indicates a state of or a result of performing an operation on one or more of various entries of the storage device. The status information STA is transmitted from the sequencer 16 and is transmitted to the input/output circuit 11.

The address register 14 temporarily stores the address information ADD received by the storage device 1. The address information ADD includes, in one example, a plane address, a block address, a page address, and a column address. The plane address, the block address, the page address, and the column address specify the plane PLN, the block BLK, the word line WL, and the bit line BL, respectively. The address information ADD is received from outside the storage device 1, the memory controller in one example, by the input/output circuit 11, and is transmitted to the address register 14.

The command register 15 temporarily stores the command CMD received by the storage device 1. The command CMD instructs various operations including data read, data write, and data erase to the storage device 1.

The sequencer 16 is a circuit that controls the operation of the entire storage device 1. The sequencer 16 executes the various operations including data read, data write, and data erase by controlling the driver 17, and the row decoder 21 and the sense amplifier 22 of each plane PLN, based on the command CMD received from the command register 15. The sequencer 16 transmits a ready/busy signal RY/⁻BY. The ready/busy signal RY/⁻BY indicates whether the storage device 1 is in a ready state or in a busy state, and indicates the busy state by the low level. The storage device 1 receives the command when it is in the ready state, and does not receive the command when it is in the busy state.

The driver 17 is a circuit that applies various voltages required for the operation of the storage device 1 to some components. The driver 17 receives a power supply voltage from the outside of the storage device 1, and generates a plurality of voltages from the power supply voltage. The driver 17 supplies the generated voltages to the memory cell array 20, the sense amplifier 22, and the row decoder 21 of each plane.

The row decoder 21 is a circuit for selecting the block BLK. The row decoder 21 transfers the voltage supplied from the driver 17 to one block BLK selected based on the block address received from the address register 14.

The sense amplifier 22 is a circuit that determines data stored in the memory cell array 20. The sense amplifier 22 senses a state of the cell transistor MT, and generates read data based on the sensed state. The generated read data DAT is transmitted to the input/output circuit 11. The sense amplifier 22 receives the write data DAT, and applies various voltages to the bit line connected to the cell transistor MT based on the received write data DAT.

### 1.1.1. Memory Cell Array

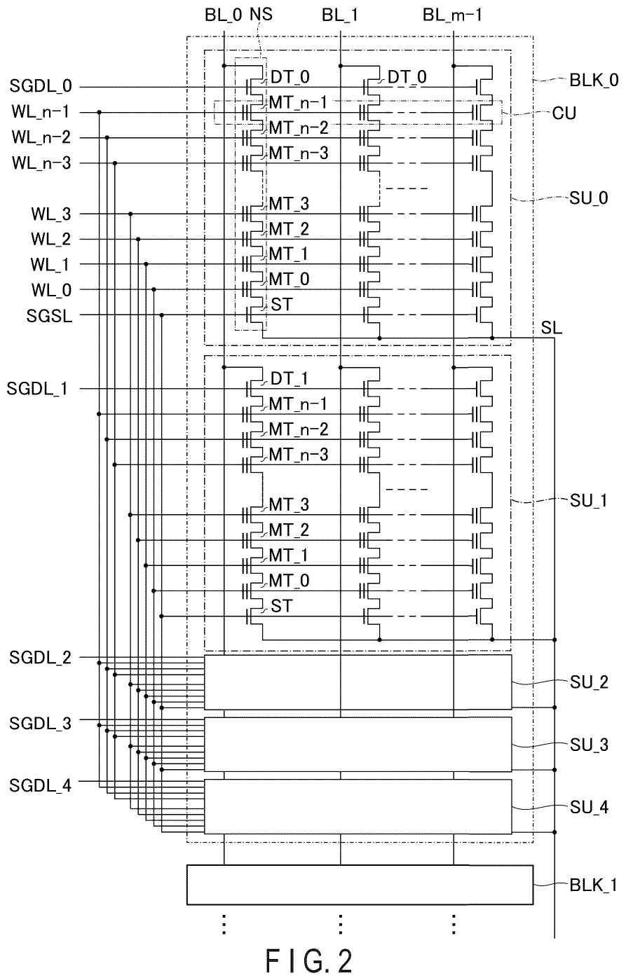

FIG. 2 is a circuit diagram of components in one block of the storage device of the first embodiment and connections of the components. The plurality of blocks BLK, all the blocks BLK for example, include the components and the connections illustrated in FIG. 2.

One block BLK includes a plurality of string units SU. FIG. 2 illustrates an example of five string units SU_0 to SU_4.

As illustrated in FIG. 2, each of m lines of bit lines BL_0 to BL_m-1 is connected to one NAND string NS from each of the string units SU_0 to SU_4 in each block BLK. A variable m is a positive integer.

Each NAND string NS includes one selection gate transistor ST, n pieces of the cell transistors MT (MT_0 to MT_n-1), and one selection gate transistor DT (DT_0, DT_1, DT_2, DT_3, or DT_4). A variable n is a positive integer. The cell transistor MT functions as a memory cell, and is an element that stores data in a nonvolatile manner. The cell transistor MT includes a control gate electrode or a gate electrode (word line WL), and a charge storage film, and stores data in a nonvolatile manner based on an electric charge in the charge storage film. The data is written to the cell transistor MT by injection of electrons to the charge storage film.

The selection gate transistor ST, the cell transistors MT_0 to MT_n-1, and the selection gate transistor DT are connected in series between a source line SL and one bit line BL in the order.

The plurality of NAND strings NS connected respectively to the plurality of different bit lines BL constitute one string unit SU. In each string unit SU, the control gate electrodes of the cell transistors MT_0 to MT_n-1 are connected respectively with word lines WL_0 to WL_n-1. A set of the cell transistors MT sharing the word line WL in one string unit SU is referred to as a cell unit CU.

The selection gate transistors DT_0 to DT_4 belong to the string units SU_0 to SU_4, respectively. In FIG. 2, the selection gate transistors DT_2, DT_3, and DT_4 are not illustrated. A gate of the selection gate transistor DT_0 in each of the plurality of NAND strings NS of the string unit SU_0 is connected to a selection gate line SGDL_0. Similarly, gates of the selection gate transistors DT_1, DT_2, DT_3, and DT_4 in each of the plurality of NAND strings NS of the string units SU_1, SU_2, SU_3, and SU_4 respectively are connected to selection gate lines SGDL_1, SGDL_2, SGDL_3, and SGDL_4.

A gate of the selection gate transistor ST is connected to a selection gate line SGSL.

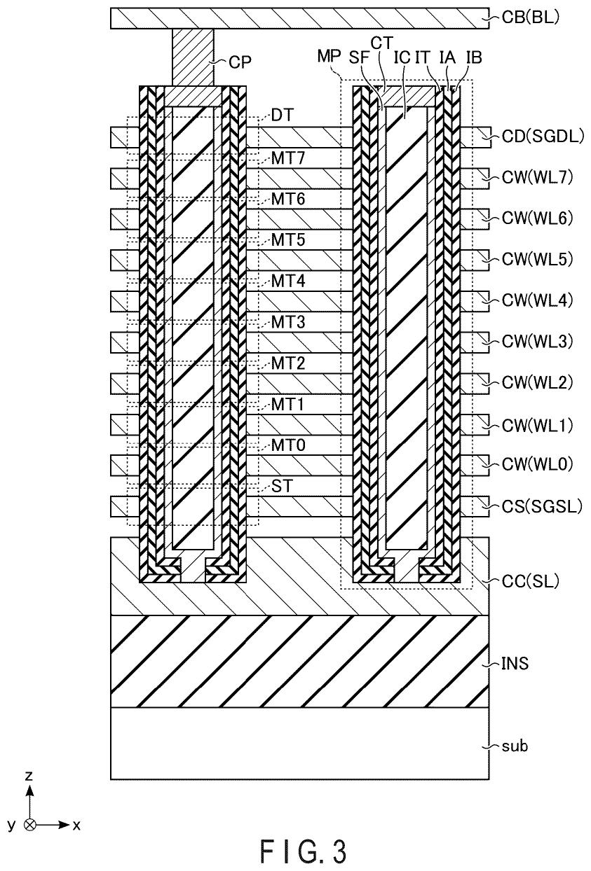

Each block BLK may have any structure as long as a circuit illustrated in FIG. 2 is realized. For example, each block BLK may have a structure illustrated in FIG. 3. FIG. 3 schematically illustrates an example of a structure of a part of a memory cell array of the storage device of the first embodiment.

As illustrated in FIG. 3, an insulator INS is provided on the upper surface of a substrate sub. On the upper surface of the insulator INS, a conductor CC is provided. The conductor CC functions as a part of the source line SL. FIG. 3 illustrates an example in which the variable n is 8.

Above the conductor CC, one conductor CS, n pieces, that is, 8 pieces of conductors CW, and a conductor CD are provided. The conductors CS, CW, and CD are lined up along the z-axis at regular intervals, and extend along the y-axis. The conductors CS, CW, and CD function as the selection gate line SGSL, the word lines WL_0 to WL_7, and the selection gate line SGDL of each NAND string NS, respectively.

Above the conductor CC, a memory pillar MP is provided. The memory pillar MP passes through the conductors CS, CW, and CD. The lower surface of the memory pillar MP is positioned in the conductor CC. The memory pillar MP includes an insulator IC, a semiconductor (layer) SF, a tunnel insulator (layer) IT, a charge storage film IA, a block insulator (layer) IB, and a conductor (layer) CT.

The insulator IC has a columnar shape that extends along the z-axis, and is positioned at a center of the memory pillar MP. The semiconductor SF covers a side face of the insulator IC. The semiconductor SF is in contact with the conductor CC at a part of the lower surface. The semiconductor SF functions as a channel region and a body of the cell transistors MT and the selection gate transistors DT and ST. The channel region is a region where a channel is formed.

The tunnel insulator IT covers a side face of the semiconductor SF. The charge storage film IA is an insulator or a conductor, and covers a side face of the tunnel insulator IT. The block insulator IB covers the side face of the tunnel insulator IT.

The conductor CT covers the upper surface of the insulator IC and the upper surface of the semiconductor SF.

The upper surfaces of some conductors CT are connected to a conductor CB via a conductive plug CP. The conductor CB extends along the x-axis and is lined up along the y-axis. The conductor CB functions as the bit line BL.

Those parts that intersect the conductors CS, CW, and CD of each memory pillar MP function as the selection gate transistor ST, the cell transistors MT, and the selection gate transistor DT, respectively.

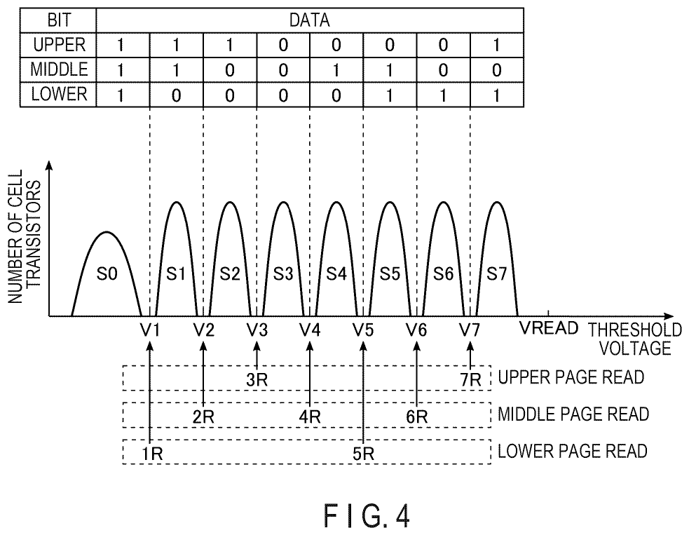

The storage device 1 can store data of two bits or more in one cell transistor MT. FIG. 4 illustrates an example of a distribution of threshold voltages of cell transistors storing 3-bit data of the storage device of the first embodiment and data mapping. The threshold voltage of each cell transistor MT has a level corresponding to the stored data, based on an amount of electrons in the charge storage film IA. In the case of storing three bits, each cell transistor MT is in one state corresponding to the threshold voltage among “S0”, “S1”, “S2”, “S3”, “S4”, “S5”, “S6”,and “S7” states. The cell transistors MT in the “S0”, “S1”, “S2”, “S3”, “S4”, “S5”, “S6”, and “S7” states have successively increasing threshold voltages. When the threshold voltage is lowered by data erase, the cell transistors MT are transitioned to the “S0” state.

During data write, the cell transistor MT which is to be written is maintained in the “S0” state or transitioned to one of the “S1”, “S2”, “S3”, “S4”, “S5”, “S6”, and “S7” states, based on data to be written. Even the plurality of cell transistors MT storing the same 3-bit data may have the threshold voltages different from each other. A set of the threshold voltages corresponding to one state is referred to as a threshold voltage lobe.

The 3-bit data can be assigned to each state in an arbitrary manner. In one example, each state is assigned the 3-bit data below. For “ABC” in the following description, A, B, and C indicate values of upper, middle, and lower bits, respectively.
“S0” state: “111”
“S1” state: “110”
“S2” state: “100”
“S3” state: “000”
“S4” state: “010”
“S5” state: “011”
“S6” state: “001”
“S7” state: “101”

Data read is based on determination of the state of the cell transistor MT which is to be read. In order to determine the state, a plurality of read voltages VCGR having sizes different from each other are used. The cell transistor MT is OFF even when the read voltage VCGR is received at the control gate electrode in the case of having the threshold voltage equal to or larger than the read voltage VCGR, and is ON when the read voltage VCGR is received at the control gate electrode in the case of having the threshold voltage smaller than the read voltage VCGR. Based on this, whether the threshold voltage of the cell transistor MT which is to be read exceeds the read voltage VCGR is determined.

Whether the cell transistor MT which is to be read is in a state above the “S0”, “S1”,“S2”, “S3”, “S4”, “S5”, “S6”, and “S7” states is determined using read voltages V1, V2, V3, V4, V5, V6, and V7, respectively. The read voltages V1, V2, V3, V4, V5, V6, and V7 have increasing voltage levels. Data read by application of the read voltages V1, V2, V3, V4, V5, V6, and V7 is referred to as 1R, 2R, 3R, 4R, 5R, 6R, and 7R, respectively.

A set of bits at the same bit position of the cell transistors MT in one cell unit CU make up one page. A set of the bits at the least significant bit position of the cell transistors MT in each cell unit CU is referred to as a lower page. A set of the bits at the second least significant bit position of the cell transistors MT of each cell unit CU is referred to as a middle page. A set of the bits at the third least significant bit position of the cell transistors MT of each cell unit CU is referred to as an upper page.

For reading the lower page, 1R and 5R are used. The data of the lower page can be determined by 1R and 5R.

For reading the middle page, 2R, 4R, and 6R are used. The data of the middle page can be determined by 2R, 4R, and 6R.

For reading the upper page, 3R and 7R are used. The data of the upper page can be determined by 3R and 7R.

A voltage VREAD has a level that turns ON the cell transistor MT regardless of the state to which the cell transistor MT belongs.

### 1.1.2. Driver and Row Decoder

FIG. 5 illustrates components of the driver and the row decoder of the storage device of the first embodiment and connections of the components.

As illustrated in FIG. 5, the driver 17 includes drivers (CGdrv) CGD that are as many as the word lines WL included in one NAND string NS. FIG. 5 illustrates an example in which the variable n is 8, and illustrates CG drivers CGD0 to CGD7.

The CG drivers CGD0 to CGD7 output the voltage when instructed by the sequencer 16, respectively. The CG drivers CGD0 to CGD7 supply the voltage when instructed to wires CG0 to CG7, respectively.

The planes PLN_0 and PLN_1 are both connected with the wires CG0 to CG7.

A row decoder 21_0 of the plane PLN_0 includes block decoders BD0 that are as many as the blocks BLK. Each block decoder BD0 is made to correspond to one block BLK. Each block decoder BD0 is connected with a control terminal (for example, a gate) of each of switches (for example, transistors) CGSW0 that are as many as the word lines WL included in one NAND string NS. Each block decoder BD0 is selected based on the block address. The selected block decoder BD0 connects the wires CG0 to CG7 connected with the block decoder BD0 to the word lines WL_0 to WL_7 of the block BLK to which the block decoder BD0 corresponds, respectively. As a result of the connection made by the block decoder BD0, voltages of the wires CG0 to CG7 are transferred to the word lines WL_0 to WL_7, respectively.

A row decoder 21_1 of the plane PLN_1 includes block decoders BD1 that are as many as the blocks BLK. Each block decoder BD1 is made to correspond to one block BLK. Each block decoder BD1 is connected with a control terminal (for example, a gate) of each of switches (for example, transistors) CGSW1 that are as many as the word lines WL included in one NAND string NS. Each block decoder BD1 is selected based on the block address. The selected block decoder BD1 connects the wires CG0 to CG7 connected with the block decoder BD1 to the word lines WL_0 to WL_7 of the block BLK to which the block decoder BD1 corresponds, respectively. As a result of the connection made by the block decoder BD1, voltages of the wires CG0 to CG7 are transferred to the word lines WL_0 to WL_7, respectively.

### 1.1.3. Sense Amplifier

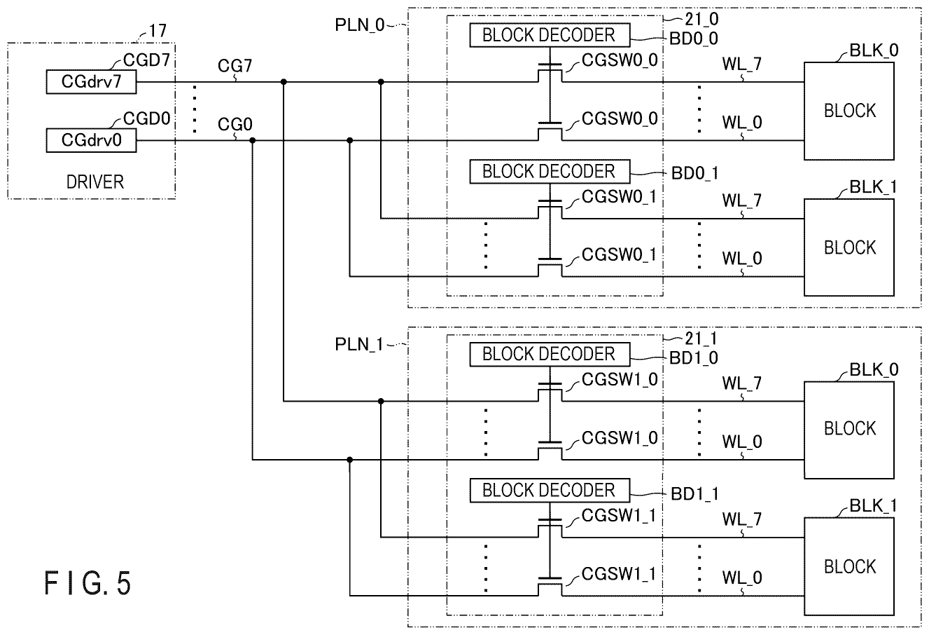

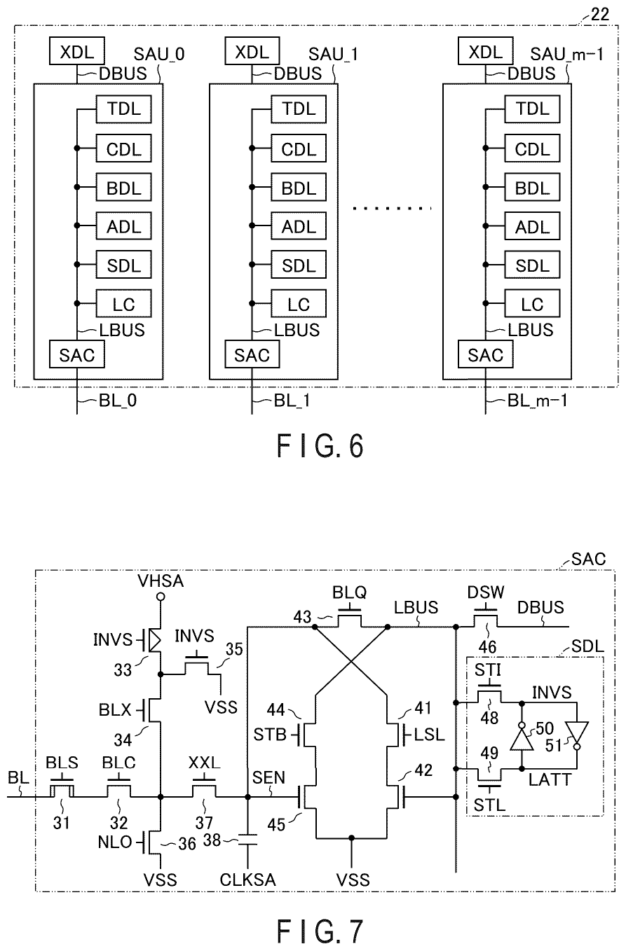

FIG. 6 illustrates elements and connections of the sense amplifier of the storage device of the first embodiment. The sense amplifier 22 includes sense amplifier units SAU that are as many as the bit lines BL. Each sense amplifier unit SAU includes a sense amplifier circuit SAC, data latches SDL and XDL, a plurality of, four for example, data latches ADL, BDL, CDL, and TDL, and a logical operation circuit LC.

The data latches SDL, ADL, BDL, CDL, and TDL are connected with a bus LBUS. Each of the data latches SDL, ADL, BDL, CDL, and TDL can store 1-bit data.

The data latch XDL is connected with one sense amplifier unit SAU via a bus DBUS. The bus DBUS is connected with the input/output circuit 11.

The sense amplifier circuit SAC is connected with one bus LBUS and one bit line BL. The sense amplifier circuit SAC is electrically connected with one selected cell transistor MT via one bit line BL during data read. The selected cell transistor MT is the cell transistor MT selected as a target of data read or data write. Each sense amplifier circuit SAC senses the voltage having a level that is based on the threshold voltage of the selected cell transistor MT on a node in the sense amplifier circuit SAC. The sense amplifier circuit SAC outputs data indicating which of two states the cell transistor MT belongs to, based on a result of sensing. The two states of the cell transistor MT are expressed as “0” data or “1” data. The data is stored in the data latch SDL connected with the sense amplifier circuit SAC.

The logical operation circuit LC is connected with the bus LBUS. The logical operation circuit LC can perform logical operations on the data stored in the data latches SDL, ADL, BDL, CDL, and TDL connected with the logical operation circuit LC. The logical operations include a NOT operation, an OR operation, an AND operation, an XOR operation, and an XNOR operation.

FIG. 7 is a circuit diagram of the sense amplifier circuit of the storage device of the first embodiment. Each sense amplifier circuit SAC further includes a p-type MOSFET (metal oxide semiconductor field effect transistor) 33, n-type MOSFETs 31, 32, 34, 35, 36, 37, 41, 42, 43, 44, and 46, and a capacitor 38.

The transistors 31, 32, and 37 are connected in series between the bit line BL connected with the sense amplifier circuit SAC and a node SEN. The transistor 31 receives a signal BLS at the gate. The transistor 32 receives a signal BLC at the gate. The transistor 37 receives a signal XXL at the gate.

The transistors 33, 34, and 36 are connected in series between a node VHSA and a node VSS. The node VHSA receives a power supply voltage of the sense amplifier 22. The node VSS receives a ground voltage VSS. The transistor 33 is connected with a node INVS at the gate. The transistor 34 receives a signal BLX at the gate. The transistor 36 receives a signal NLO at the gate.

The transistor 35 is connected between a node to which the transistors 33 and 34 are connected and the node VSS. The transistor 35 is connected with the node INVS at the gate.

The capacitor 38 is connected with the node SEN at one end, and receives a signal CLKSA at the other end.

The transistors 41 and 42 are connected in series in the order between the node SEN and the node VSS. The transistor 41 receives a signal LSL at the gate. The transistor 42 is connected with the bus LBUS at the gate.

The transistor 43 is connected between the node SEN and the bus LBUS. The transistor 43 receives a signal BLQ at the gate.

The transistors 44 and 45 are connected in series between the bus LBUS and the node VSS. The transistor 44 receives a signal STB at the gate. The transistor 45 is connected with the node SEN at the gate.

The transistor 46 is connected between the bus LBUS and the bus DBUS. The transistor 46 receives a signal DSW at the gate.

A latch circuit SLC includes n-type MOSFETs 48 and 49, and inverter circuits 50 and 51.

The transistor 48 is connected between the bus LBUS and the node INVS. The transistor 48 receives a signal STI at the gate.

The transistor 49 is connected between the bus LBUS and a node LATT. The transistor 49 receives a signal STL at the gate.

The inverter circuit 50 is connected with the node LATT at its input, and is connected with the node INVS at its output.

The inverter circuit 51 is connected with the node INVS at its input, and is connected with the node LATT at its output.

In one example, one, two or more, or all of the signals BLS, BLC, XXL, BLX, NLO, CLKSA, LSL, BLQ, and STB are supplied from the sequencer 16.

### 1.2. Operation

### 1.2.1. Outline of Data Write

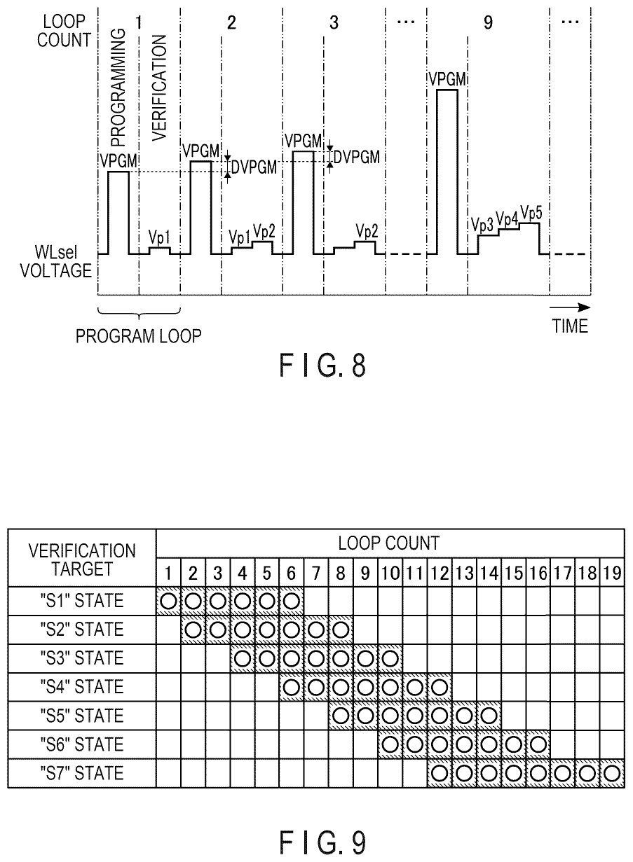

FIG. 8 is a timing diagram illustrating a write operation in the storage device of the first embodiment. As illustrated in FIG. 8, the storage device 1 repeatedly executes a program loop during the write operation. FIG. 8 illustrates the number of times of executing the program loop (hereinafter, referred to as a loop count), and a voltage (WLsel voltage) of a word line WLsel. The word line WLsel is a word line connected with the cell unit CU on which the write operation is to be performed. Each program loop includes programming and verification.

The programming is an operation for raising the threshold voltage of the cell transistor MT. During the programming, a plurality of cell transistors MTsel connected to the word line WLsel are set to a programming state or a programming inhibition state, depending on a target state of each cell transistor MTsel. The target state is a state that each cell transistor MTsel is to be transitioned to, based on data to be written. The cell transistor MTsel is set to the programming state in the case of having the threshold voltage smaller than the voltage determined to be included in the target state. The cell transistor MTsel is set to the programming inhibition state in the case of having the threshold voltage equal to or larger than the voltage determined to be included in the target state.

During the programming, a programming voltage VPGM of a variable size is applied to the word line WLsel. The programming voltage VPGM is a high voltage capable of raising the threshold voltage of the cell transistor MTsel.

The programming voltage VPGM is increased every time the loop count increases. An increase width DVPGM of the programming voltage VPGM may have an arbitrary size. When the programming voltage VPGM is applied to the word line WLsel, the threshold voltage of the cell transistor MTsel in the programming state is raised. Raising of the threshold voltage of the cell transistor MTsel in the programming inhibition state is suppressed.

The verification is an operation of confirming whether the threshold voltage of the cell transistor MTsel has the threshold voltage equal to or larger than the voltage determined to be included in the target state, and is a read operation.

The sequencer 16 executes the verification to the cell transistor MTsel having a specific target state within each program loop.

In the verification, whether the threshold voltage of the cell transistor MTsel is equal to or larger than a verification voltage Vp of a certain level is determined. Each sense amplifier unit SAU outputs data based on whether the threshold voltage of the cell transistor MTsel connected therewith is equal to or larger than the verification voltage Vp. In the case where the threshold voltage of the cell transistor MTsel is equal to or larger than the verification voltage Vp, data indicating passing of the verification is output. The verification voltage Vp has a level depending on the target state, and is lower than the minimum threshold voltage of the target state. In one example, verification voltages Vp1, Vp2, Vp3, Vp4, Vp5, Vp6, and Vp7 for each of the “S0”, “S1”, “S2”, “S3”, “S4”, “S5”, “S6”, and “S7” states are same as the read voltages V1, V2, V3, V4, V5, V6, and V7, respectively. In another example, the verification voltages Vp1, Vp2, Vp3, Vp4, Vp5, Vp6, and Vp7 are slightly lower than the read voltages V1, V2, V3, V4, V5, V6, and V7, respectively.

On the other hand, in the case where the threshold voltage of the cell transistor MTsel is smaller than the verification voltage, data indicating failing of the verification is output. Each sense amplifier unit SAU stores the data indicating a result of the verification in any one data latch ADL, BDL, CDL, or TDL. When the verification in one program loop is completed, the sequencer 16 sets each cell transistor MTsel in the programming state or the programming inhibition state based on the verification result, and starts the next program loop.

The storage device 1 can execute a detection operation after an arbitrary program loop. In the detection operation, the number of the cell transistors MTsel that have passed the verification is counted for each target state. Then, the sequencer 16 determines whether write of the target state is completed based on a count value, for each target state. In one example, when the count value exceeds a certain percentage of m (which is the total number of the cell transistors MT in one cell unit CU), it is determined that the write is completed. When it is determined that the write of all the states is completed, in the status register 13, information indicating pass is stored as a write status. On the other hand, when it is determined that the write of at least one state is not completed even though execution of the program loop for a predetermined number of times (in the case of an example in FIG. 9 to be described later, 19 times) is completed, in the status register 13, information indicating fail is stored as the write status. The write status is a part of the status information STA.

### 1.2.2. Program Loop

FIG. 9 illustrates an example of verification targets of each program loop in the write operation in the storage device of the first embodiment. FIG. 9 illustrates a relation between the loop count and the target state which is to be verified. The target state which is to be verified is illustrated with a white circle.

As illustrated in FIG. 9, a kind and the number of the target states which are to be verified are different according to progress of the program loop. In the example in FIG. 9, the sequencer 16 executes the program loop 19 times at maximum. The largest number of times of the program loop is determined beforehand according to the number of times with which it is considered or assumed that the write operation is to be completed (that is, raising of the threshold voltage of the cell transistor MTsel for which the highest state is the target state is to be completed).

The sequencer 16 executes the verification with at least one state as a target, in each program loop. Specifically, the “S1” state is set as the target to be verified in the first to sixth rounds of program loop. The “S2” state is set as the target to be verified in the second to eighth rounds of program loop. The “S3” state is set as the target to be verified in the fourth to 10th rounds of program loop. The “S4” state is set as the target to be verified in the sixth to 12th rounds of program loop. The “S5” state is set as the target to be verified in the eighth to 14th rounds of program loop. The “S6” state is set as the target to be verified in the 10th to 16th rounds of program loop. The “S7” state is set as the target to be verified in the 12th to 19th rounds of program loop. In the last program loop, the verification may be omitted. That is because it is assumed that the write is to be completed by the last program loop.

### 1.2.3. Verification

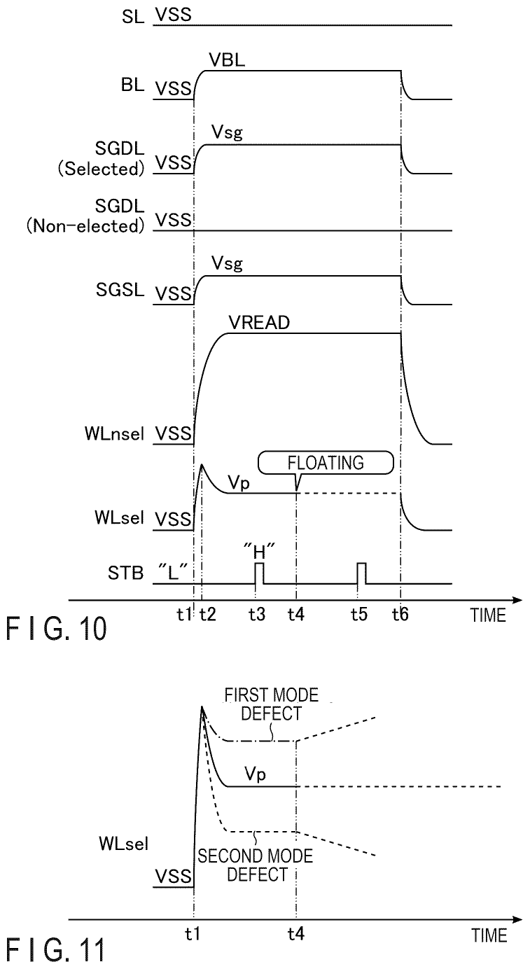

FIG. 10 is timing diagram illustration voltage changes in various wires and signals during the verification in the storage device of the first embodiment. The verification in FIG. 10 can be performed for an arbitrary state in the verification for one or more states executed during one write operation, as described later. The verification in FIG. 10 can also be performed at an arbitrary timing. The timing of executing the verification in FIG. 10 will be described later. Hereinafter, the verification described with reference to FIG. 10 is sometimes referred to as floating verification.

During the operation illustrated in FIG. 10, the block BLK including the cell unit CU to which data is to be written is connected with the CG drivers CGD0 to CGD7 via the row decoder 21. Hereinafter, the cell unit to which data is to be written is sometimes referred to as a selected cell unit CU.

The source line SL is maintained at a ground voltage VSS over a period illustrated in FIG. 10.

The non-selected selection gate lines SGDL, which exclude the selection gate line SGDL connected with the string unit SU including the selected cell unit CU, are maintained at the ground voltage VSS over the period illustrated in FIG. 10. In the description below, the “selection gate line SGDL” is the selection gate line SGDL connected with the string unit SU including the selected cell unit CU, in the description below with reference to FIG. 10.

At a point of time of start of the period illustrated in FIG. 10, the wires and the signal have the voltages below. Each of the bit line BL, the selection gate line SGDL, the selection gate line SGSL, the word line WLsel, and a non-selected word line WLnsel has the voltage VSS, and the signal STB has a low (“L”) level. The non-selected word line WLnsel is the word line WL other than the word line WLsel.

From time t1, a voltage VBL is applied to each bit line BL. The voltage VBL is higher than the voltage VSS, and is lower than the voltage VREAD. By application of the voltage VBL, each bit line BL is to have the voltage VBL.

From the time t1, a voltage Vsg is applied to the selection gate lines SGDL and SGSL. The voltage Vsg has a size to turn ON the selection gate transistors DT and ST. Thus, the selection gate lines SGDL and SGSL are to have the voltage Vsg. As a result, the voltage VBL of the bit line BL is transferred to each memory pillar MP, and each memory pillar MP is to have a voltage between the voltage VSS and the voltage VBL.

From the time t1, the voltage VREAD is applied to the non-selected word line WLnsel and the word line WLsel. Thus, the non-selected word line WLnsel is to have a voltage VREAD.

From time t2, the word line WLsel receives the voltage VREAD and then receives the verification voltage Vp. The verification voltage Vp in the floating verification may have a level for an arbitrary state. The verification voltage Vp in the floating verification may be predetermined, or may be set by a command or the like that sets a value of a parameter used in the storage device 1. By application of the verification voltage Vp, the word line WLsel discharges and the voltage of the word line WLsel decreases. As a result, the word line WLsel is to have the verification voltage Vp.

At time t3, the signal STB is temporarily turned to a high (“H”) level. As a result, the “0” data or the “1” data is obtained based on the voltage at the node SEN of each sense amplifier circuit SAC. The acquired data is stored in the data latch SDL connected with each sense amplifier circuit SAC. Hereinafter, an operation of turning the signal STB to the high level and acquiring the “0” or “1” data based on the voltage at the node SEN is referred to as a sensing operation.

From time t4, the word line WLsel is electrically floated. This is performed by disabling the CG driver CGD (one of CGD0 to CGD7) connected with the wire CG (one of CG0 to CG7) electrically connected with the word line, in one example. In another example, electric floating is performed by disabling a power supply or a voltage generation circuit in the CG driver CGD or a circuit which supplies power to the driver CGD. In a further example, it can be performed by turning OFF a switch electrically connected with the word line WLsel. In this case, the row decoder 21 is configured such that each switch CGSW can be individually turned ON or OFF by control by the block decoder BD and control different from that. As a result of the electric floating, the voltage of the word line WLsel becomes inconsistent, however, the word line WLsel maintains the voltage level before the time t4 unless the word line WLsel has become defective. Note that, here, a minute leak current such as a leak current via the transistor is not taken into consideration. That is, in the case where the leak current is generated, the voltage of the word line WLsel may become slightly lower than the voltage before the time t4. The voltage in the case where the word line WLsel is defective will be described later.

At time t5, the sensing operation is performed. The data acquired by the sensing operation is stored in the data latch ADL, BDL, CDL, or TDL other than the data latch SDL, that is connected with each sense amplifier circuit SAC. The following description is based on an example in which the data is stored in the data latch TDL.

At time t6, the ground voltage VSS is applied to each bit line BL, the selection gate lines SGDL and SGSL, the word line WLsel, and the non-selected word line WLnsel. Thus, acquisition of the data for the verification is completed.

FIG. 11 is a timing diagram illustration voltage changes in various wires during the verification in the storage device of the first embodiment. FIG. 11 illustrates the cases where the word line WLsel is defective and where the word line WLsel is normal (that is, not defective).

The storage device 1 may have a first mode defect and a second mode defect. The first mode defect refers to unintended formation of a current path between the conductors CW that are adjacent to each other and function as the word line WL. When the first mode defect occurs in the word line WLsel, during the verification (and the read operation), a current flows to the word line WLsel from the non-selected word line WLnsel short-circuited with the word line WLsel. Therefore, the voltage of the word line WLsel is not lowered to the verification voltage Vp even when the word line WLsel is discharged from the time t2. As a result, from the time t2 to the time t4, the word line WLsel maintains the voltage higher than the verification voltage Vp.

On the other hand, from the time t4, since the word line WLsel is electrically floated, application of the verification voltage Vp to the word line WLsel is stopped. As a result, from the time t4, the voltage of the word line WLsel is raised by inflow of the current from the adjacent word line WLsel.

The second mode defect refers to unintended formation of a current path between the word line WL and the memory pillar MP. The memory pillar MP has the voltage level between the voltage VSS and the voltage VBL from the time t1, and the voltage is lower than the voltage VREAD. Thus, when the second mode defect occurs in the word line WLsel, during the verification (and the read operation), a current flows out from the word line WLsel to the memory pillar MP. Therefore, the voltage of the word line WLsel becomes lower than the verification voltage Vp by the discharge of the word line WLsel from the time t2 and outflow of the current. As a result, from the time t2 to the time t4, the voltage of the word line WLsel maintains the voltage lower than the verification voltage Vp.

On the other hand, from the time t4, since the word line WLsel is electrically floated, application of the verification voltage Vp to the word line WLsel is stopped. As a result, from the time t4, the voltage of the word line WLsel is lowered by the outflow of the current from the adjacent word line WLsel.

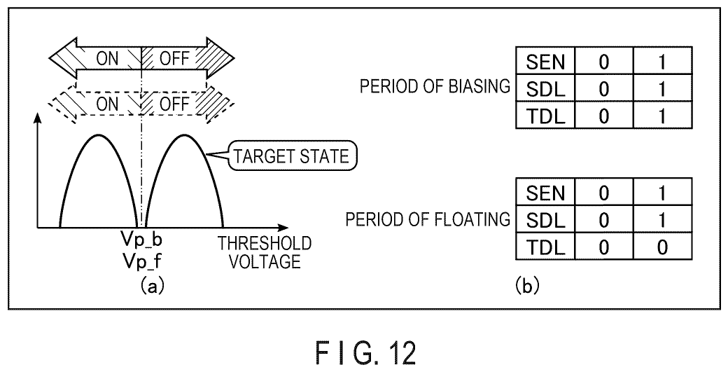

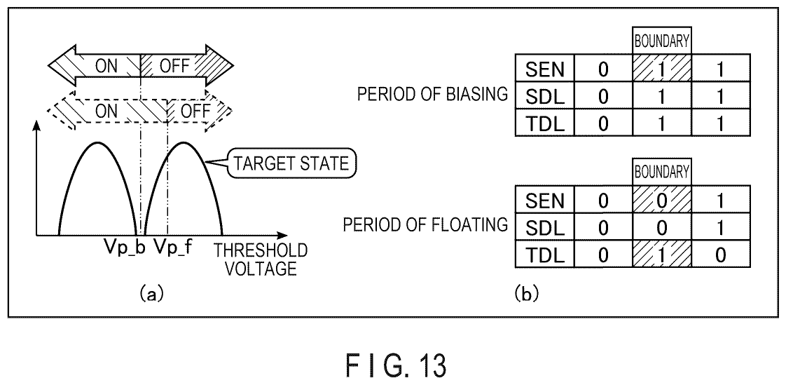

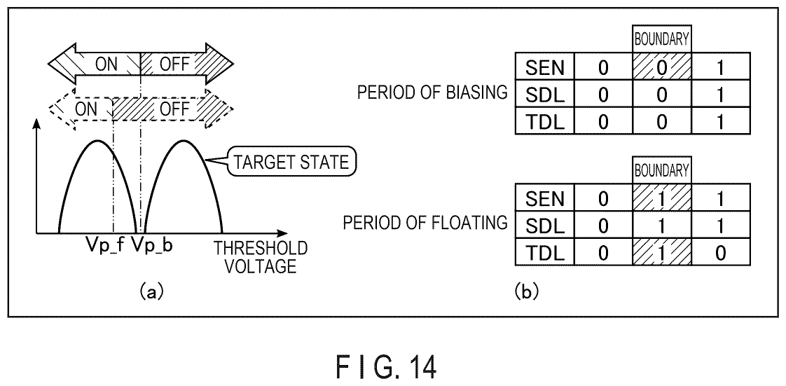

FIG. 12, FIG. 13, and FIG. 14 illustrate examples of a state and acquired data during the verification in the storage device of the first embodiment. FIG. 12 illustrates a case where the word line WLsel is normal. FIG. 13 illustrates a case where the first mode defect has occurred in the word line WLsel. FIG. 14 illustrates a case where the second mode defect has occurred in the word line WLsel. FIG. 12 to FIG. 14 illustrate, in part (a), the respective threshold voltage lobes of the target state and the state next to the target state on a low voltage side of the target state, and the cell transistors MTsel that are turned ON or OFF, respectively. The part (a) is for a period (from the time t2 to the time t4) during which the word line WLsel is biased, and a period (from the time t4 to the time t6) during which the word line WLsel is electrically floated. FIG. 12 to FIG. 14 illustrate, in part (b), a state of the node SEN at the time of the sensing operation and the data obtained by the sensing operation and stored in the data latches SDL and TDL, respectively. The part (b) is for the period during which the word line WLsel is biased and the period during which the word line WLsel is electrically floated. The operation described below is performed by the control by the sequencer 16, in one example.

In the normal case, the verification voltage Vp does not change between the period of biasing and the period of floating. Therefore, as illustrated in the part (a) in FIG. 12, the number of the cell transistors MT turned ON by receiving a verification voltage Vp_b in the period of biasing and the number of the cell transistors MT turned ON by receiving a verification voltage Vp_f in the period of floating are the same.

As illustrated in the part (b) in FIG. 12, in the period of biasing, the node SEN connected with the cell transistor MT having the threshold voltage equal to or larger than the verification voltage Vp_b is in a state (indicated as “1”) of having a voltage below a certain standard, since the cell transistor MT is OFF. On the other hand, in the period of biasing, the node SEN connected with the cell transistor MT having the threshold voltage equal to or larger than the verification voltage Vp_f is in a state (indicated as “0”) of having a voltage equal to or lower than the certain standard, since the cell transistor MT is ON.

By the sensing operation in the period of biasing, the data based on the state of each node SEN is stored in the data latch SDL in the sense amplifier unit SAU including the node SEN. When the node SEN is in a “1” state, the “1” data is stored in the data latch SDL. When the node SEN is in a “0” state, the “0” data is stored in the data latch SDL. Hereinafter, for two components included in the certain same sense amplifier unit SAU, one component is described as the component “corresponding” to the other component.

The data of each data latch SDL is stored in the corresponding data latch TDL.

Next, by the sensing operation in the period of floating, the data based on the state of each node SEN is stored in the corresponding data latch SDL. In the normal case, the state of each node SEN and the data of the corresponding data latch SDL at the time of each sensing operation are the same between the period of biasing and the period of floating.

The sequencer 16 uses the logical operation circuit LC to store the data based on the data latch TDL and the data latch SDL in the data latch TDL in each sense amplifier unit SAU. The data stored in the data latch TDL has specific data when the data in the data latch TDL and the data in the data latch SDL are different. In one example, the sequencer 16 stores a logical product of the data latch TDL and NOT of the data latch SDL in the data latch TDL. When the state of the node SEN, that is, a result obtained by the sensing operation is different between the period of biasing and the period of floating, the “1” data is stored in the data latch TDL. In this way, a set of bits in a set of m pieces of the data latches TDL is obtained. Hereinafter, the set of m pieces of the data latches TDL is sometimes referred to as a data latch set TDLS.

The sequencer 16 performs the detection operation in the program loop in which the floating verification is performed. In the detection operation, the sequencer 16 counts the bits storing the “1” data in the data latch set TDLS. The sequencer 16 determines a pass or a fail of the verification based on a count value and an arbitrary standard.

As described above with reference to FIG. 11, in the case of the first mode defect, the verification voltage Vp_f in the period of floating is higher than the verification voltage Vp_b in the period of biasing. Therefore, as illustrated in the part (a) of FIG. 13, the number of the cell transistors MT turned ON by receiving the verification voltage Vp_f is larger than the number of the cell transistors MT turned ON by receiving the verification voltage Vp_b.

Therefore, as illustrated in the part (b) of FIG. 13, a result of the verification for the cell transistor (hereinafter, sometimes referred to as a boundary cell transistor) MT having the threshold voltage between the verification voltage Vp_b in the period of biasing and the verification voltage Vp_f in the period of floating is different. That is, the node SEN connected with the boundary cell transistor MT has the “1” state in the period of biasing, and has the “0” state in the period of floating. Therefore, at the time of the detection operation, the data latch TDL connected with the boundary cell transistor MT stores the “1” data. Based on this, it is possible to determine that the first mode defect has occurred in the word line WLsel when the count value of the “1” data in the data latch set TDLS exceeds a certain standard. When it is determined that the first mode defect has occurred, the sequencer 16 stores a value indicating a fail in a WL defect status in the status register 13. That is, when it is determined that the first mode defect has not occurred in the word line WLsel as a result of the floating verification, information indicating a pass as a first WL defect status is stored in the status register 13. On the other hand, when it is determined that the first mode defect has occurred in the word line WLsel as a result of the floating verification, information indicating a fail as the first WL defect status is stored in the status register 13. The first WL defect status may be different from the write status indicating a pass/fail result of the write operation. In this case, the status information STA includes, at least, the information of one bit corresponding to the first WL defect status and the information of one bit corresponding to the write status. Alternatively, the first WL defect status and the write status may be superimposed. For example, when it is determined that the first mode defect has occurred in the word line WLsel as a result of the floating verification, information indicating that the write status is a fail may be stored in the status register 13. In this case, even in the case where it is determined that the write of all the states is completed by normal verification, when it is determined that the first mode defect has occurred in the word line WLsel, the information indicating that the write status is a fail is stored in the status register 13.

As described above with reference to FIG. 11, in the case of the second mode defect, the verification voltage Vp_f in the period of floating is lower than the verification voltage Vp_b in the period of biasing. Therefore, as illustrated in the part (a) of FIG. 14, the number of the cell transistors MT turned ON by receiving the verification voltage Vp_f is smaller than the number of the cell transistors MT turned ON by receiving the verification voltage Vp_b.

Therefore, as illustrated in the part (b) of FIG. 14, the node SEN connected with the boundary cell transistor MT has the “0” state in the period of biasing, and has the “1” state in the period of floating. Therefore, at the time of the detection operation, the data latch TDL connected with the boundary cell transistor MT stores the “1” data. Based on this, it is possible to determine that the second mode defect has occurred in the word line WLsel when the count value of the “1” data in the data latch set TDLS exceeds the certain standard. When it is determined that the second mode defect has occurred, the sequencer 16 stores the value indicating a fail in the WL defect status in the status register 13. That is, when it is determined that the second mode defect has not occurred in the word line WLsel as a result of the floating verification, information indicating a pass as a second WL defect status is stored in the status register 13. On the other hand, when it is determined that the second mode defect has occurred in the word line WLsel as a result of the floating verification, information indicating a fail as the second WL defect status is stored in the status register 13. The second WL defect status may be different from first WL defect status and the write status. In this case, the status information STA includes, at least, the information of one bit corresponding to the second WL defect status, the information of one bit corresponding to the first WL defect status, and the information of one bit corresponding to the write status. Alternatively, the first WL defect status and the second WL defect status may be managed as a defect status in a superimposed manner. In this case, when it is determined that one of the first mode defect and the second mode defect has occurred in the word line WLsel as a result of the floating verification, information indicating that the WL defect status is a fail is stored in the status register 13. Similarly, when it is determined that neither of the first mode defect and the second mode defect has occurred in the word line WLsel as a result of the floating verification, information indicating that the WL defect status is a pass is stored in the status register 13. Further, the first WL defect status, the second WL defect status, and the write status may be superimposed. For example, when it is determined that one of the first mode defect and the second mode defect has occurred in the word line WLsel as a result of the floating verification, information indicating that the write status is a fail may be stored in the status register 13. In this case, even in the case where it is determined that the write of all the states is completed by normal verification, when it is determined that one of the first mode defect and the second mode defect has occurred in the word line WLsel, the information indicating that the write status is a fail is stored in the status register 13.

Note that, in the case of failing the floating verification when the planes PLN_0 and PLN_1 are operated in parallel, in which of the planes PLN_0 and PLN_1 a defect has occurred is not recognized just by detecting a fail. However, it is possible to specify the plane PLN by performing the floating verification in a state where the block decoder BD of the block specified by the block address in one plane PLN is turned to a non-selected state.

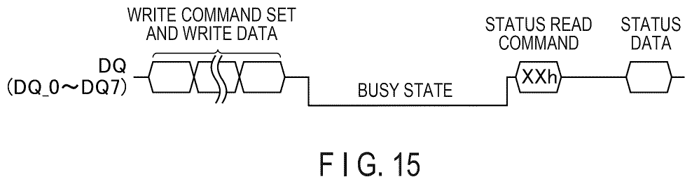

FIG. 15 illustrates an example of input/output signals transmitted and received between the storage device of the first embodiment and the outside. As illustrated in FIG. 15, the storage device 1 receives a write command set and write data from the outside. The write command set instructs a write operation to a page to which the write data is to be written.

When the write command set and the write data are received, the storage device 1 executes the instructed write operation, and enters the busy state. When the write operation is ended, the storage device 1 returns to the ready state.

The storage device 1 enters the ready state, and receives a status read command from the outside. The status read command specifies an address, and also instructs transmission of the data of the specified address in the status register 13. When the address of the WL defect status is specified in the status read command, the storage device 1 transmits status data indicating the WL defect status.

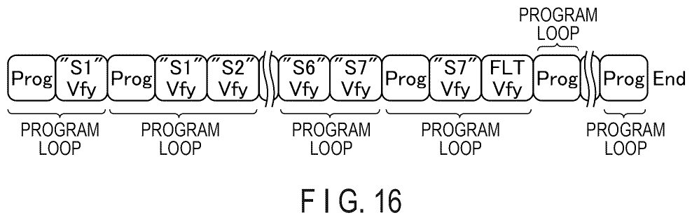

FIG. 16 to FIG. 19 illustrate examples of the timing of the operation of the storage device of the first embodiment. FIG. 16 to FIG. 19 illustrate examples of the timing of performing the floating verification and an instruction of execution of the floating verification. In FIG. 16 to FIG. 19, the programming is described as “Prog”, the verification with an “S#” state (# is a positive integer) as a target is described as ““S#”Vfy”, and the floating verification is described as “FLTVfy”.

FIG. 16 is based on an example in which the verification in the last program loop is omitted. In the example in FIG. 16, the floating verification is performed following the first verification only for the last state during the program loop. In the present example, the sequencer 16 performs the floating verification after the verification of the “S7” state in the program loop (in the example in FIG. 9, the 17th round of program loop) in which the verification of only the “S7” state is executed for the first time.

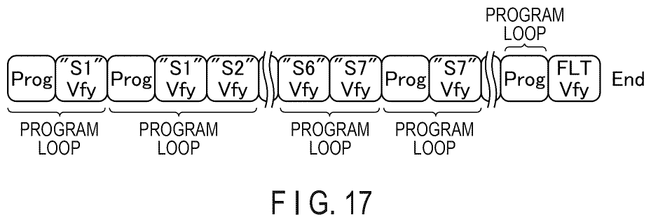

FIG. 17 is based on an example in which the verification in the last program loop is omitted. In the example in FIG. 17, the sequencer 16 performs the floating verification after the programming in the last program loop (in the example in FIG. 9, the 19th round of program loop).

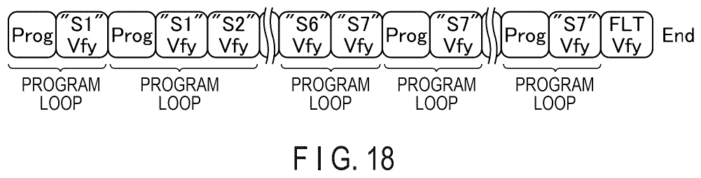

FIG. 18 is based on an example in which the verification in the last program loop is performed. In the example in FIG. 18, the sequencer 16 performs the floating verification following the normal verification (in the present example, the verification of the “S7” state) in the last program loop (in the example in FIG. 9, the 19th round of program loop).

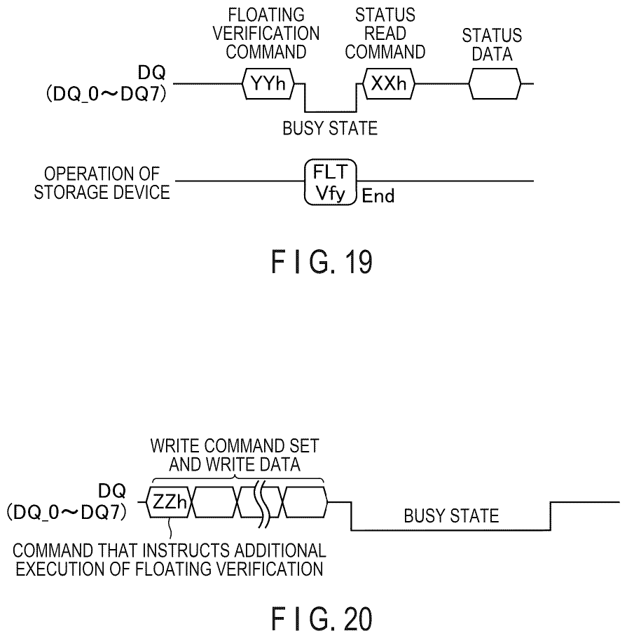

In the example of FIG. 19, the floating verification is performed alone. For this purpose, the storage device 1 receives a floating verification command, as illustrated in FIG. 19. The floating verification command specifies a target page or cell unit CU. When the floating verification command is received, the storage device 1 performs the instructed floating verification.

The operation described with reference to FIG. 16 to FIG. 18 may be performed every time the write command set is received, or may be performed when a command specifying the floating verification is included at a head of the write command set as illustrated in FIG. 20. Further, when the operation is performed every time the write command set is received, a frequency of executing the floating verification may be set by a command that sets various parameters of the storage device 1. In one example, the storage device 1 performs the operation described with reference to FIG. 16, FIG. 17, or FIG. 18 every time the write command set is received for a set number of times, and does not perform the floating verification in the other situations.

### 1.3. Advantage (Effect)

According to the first embodiment, as described below, a storage device that stores data with high accuracy is provided.

As described above with reference to FIG. 11, when the first mode defect occurs in the word line WLsel, the word line WLsel has a verification voltage Vpv higher than an intended voltage level. Then, the larger number of the cell transistors MT than the number in the normal case are turned ON. The boundary cell transistor MT generated in this way fails the verification while passing the verification in the normal case. As a result, the boundary cell transistor MT is set to the programming state in the next program loop. Thus, occurrence of the first mode defect forms a state where the threshold voltage of the cell transistor MT transitioned to the target state is high and the threshold voltage lobe of the target state is transitioned to a high voltage side. This is erroneous write and hinders accurate storage of data.

By a same principle, when the second mode defect occurs in the word line WLsel, the smaller number of the cell transistors MT than the number in the normal case are turned ON. The boundary cell transistor MT generated in this way passes the verification while failing the verification in the normal case. As a result, the boundary cell transistor MT is set to the programming inhibition state in the next program loop. Thus, occurrence of the second mode defect forms a state where the threshold voltage of the cell transistor MT transitioned to the target state is low and the threshold voltage lobe of the target state is transitioned to a low voltage side. This is an erroneous write operation and hinders accurate storage of data.

Further, when the plurality of planes are operated in parallel, as described above with reference to FIG. 5, the word line WLsel with the first or second mode defect in a certain plane PLN is connected with the word line WLsel in a different plane PLN via the row decoder 21. Therefore, a defect in one plane PLN affects the different plane PLN. That is, even when the first or second mode defect has not occurred in the different plane PLN, an erroneous write operation in the plane PLN may be performed.

According to the first embodiment, the floating verification is performed. In the floating verification, the word line WLsel is electrically floated after being biased, and a result of the sensing operation in the period of biasing and a result of the sensing operation in the period of floating are compared. While the result of the sensing operation is the same between the period of biasing and the period of floating in the normal case, the result of the sensing operation is different between the period of biasing and the period of floating in the case of the first or second mode defect. Thus, by the detection operation using the difference, the first or second mode defect can be detected. For example, when the first or second mode defect is detected, by writing data of a defective cell unit CU to a different cell unit CU without using the defective cell unit CU connected with the detected word line WLsel, the data can be stored with high accuracy. In addition, erroneous write in a normal different plane PLN due to a defect in one plane PLN can be suppressed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device comprising:
a memory cell transistor;
a bit line connected to the memory cell transistor;
a sense amplifier unit connected to the bit line;
a word line connected to the memory cell transistor; and
a control circuit connected to the sense amplifier unit and configured to execute a first operation, wherein
the first operation includes
during a first period, supplying a first voltage to the word line and acquiring first data based on a first current flowing to the bit line, and
during a second period following the first period, placing the word line in an electrically floating state and acquiring second data based on a second current flowing to the bit line.

2. The semiconductor storage device of claim 1, wherein the first data and the second data are based on a threshold voltage of the memory cell transistor.

3. The semiconductor storage device of claim 1, wherein the control circuit is configured to generate third data based on the first data and the second data, and first state data based on the third data is output to an external memory controller when a first command is received from the memory controller.

4. The semiconductor storage device of claim 3, wherein the third data has a first value when the first data and the second data are different, and has a second value when the first data and the second data are same.

5. The semiconductor storage device of claim 1, further comprising:
a driver configured to apply the first voltage to the word line.

6. The semiconductor storage device of claim 5, wherein the word line is placed in the electrically floating state by disconnecting the word line from the driver.

7. The semiconductor storage device of claim 5, wherein the word line is placed in the electrically floating state by disabling the driver.

8. The semiconductor storage device of claim 5, further comprising:
a second memory cell transistor connected between the memory cell transistor and the bit line; and
a second word line connected to the second memory cell transistor, wherein
the driver is also connected to the second word line, and
the driver supplies a second voltage higher than the first voltage to the second word line during the first period and the second period.

9. The semiconductor storage device of claim 1, wherein the control circuit is configured to perform the first operation during a time period in which a programming operation to raise a threshold voltage of the memory cell transistor is repeated multiple times in response to a command to perform a write operation.

10. The semiconductor storage device of claim 1, wherein the control circuit is configured to perform the first operation after a time period in which a programming operation to raise a threshold voltage of the memory cell transistor is repeated multiple times in response to a command to perform a write operation.

11. The semiconductor storage device of claim 1, wherein the control circuit is configured to perform the first operation each time a write operation is performed.

12. The semiconductor storage device of claim 1, wherein the control circuit is configured to perform the first operation in response to a command set that includes a command to perform a write operation and a command to perform the first operation.

13. The semiconductor storage device of claim 1, wherein the control circuit is configured to perform the first operation in response to a command to perform the first operation received independently of a command to perform a write operation.

14. A semiconductor storage device comprising:
a plurality of N memory cell transistors, where N is an integer greater than 1;
a plurality of N bit lines respectively connected to the memory cell transistors;
a plurality of N sense amplifier units respectively connected to the bit lines;
a word line connected to the N memory cell transistors in common;
a driver configured to supply a first voltage to the word line; and
a control circuit connected to the sense amplifier units and the driver and configured to execute a first operation, wherein
the first operation includes
during a first period, supplying a first voltage to the word line and acquiring N-bit first data based on N first currents respectively flowing to the bit lines, and
during a second period following the first period, placing the word line in an electrically floating state, and acquiring N-bit second data based on N second currents respectively flowing to the bit lines.

15. The semiconductor storage device of claim 14, wherein the control circuit is configured to generate N-bit third data based on the N-bit first data and the N-bit second data, and first state data based on the N-bit third data is output to an external memory controller when a first command is received from the memory controller.

16. The semiconductor storage device of claim 15, wherein
the first bit to the i-th bit of the N-bit first data are respectively based on respective threshold voltages of the N memory cell transistors, and
the first bit to the i-th bit of the N-bit second data are respectively based on the respective threshold voltages of the N memory cell transistors.

17. The semiconductor storage device of claim 14, wherein the control circuit is configured to perform the first operation during a time period in which a programming operation to raise a threshold voltage of the memory cell transistors is repeated multiple times in response to a command to perform a write operation.

18. The semiconductor storage device of claim 14, wherein the control circuit is configured to perform the first operation after a time period in which a programming operation to raise a threshold voltage of the memory cell transistors is repeated multiple times in response to a command to perform a write operation.

19. The semiconductor storage device of claim 14, wherein the control circuit is configured to perform the first operation each time a write operation is performed.

20. The semiconductor storage device of claim 14, wherein the control circuit is configured to perform the first operation in response to a command set that includes a command to perform a write operation and a command to perform the first operation.
